(19) United States
(12) Patent Application Publication
(10) Pub. No.: US 2011/0068771 A1
(43) Pub. Date: Mar. 24, 2011

(54) CURRENT SENSOR

(75) Inventors: Hiroshi Ueno, Aichi (JP); Yuji Inagaki, Aichi (JP)

(73) Assignee: KABUSHIKI KAISHA TOKAI RIKA DENKI SEISAKUSHO, Aichi (JP)

(21) Appl. No.: 12/879,557

(22) Filed: Sep. 10, 2010

(30) Foreign Application Priority Data
Sep. 18, 2009 (JP) 2009-217745

(51) Int. Cl. G01R 15/18

(52) U.S. Cl. 324/117 R

(57) ABSTRACT

A current sensor for outputting a detection signal corresponding to a current flowing through a bus bar. The current sensor includes a magnetic core that concentrates and amplifies a magnetic field generated by the current near a detection portion of the bus bar. A magnetic detection element detects the magnetic field concentrated by the magnetic core and outputs an electrical signal corresponding to the detected magnetic field. The detection portion of the bus bar and the magnetic core are molded integrally with each other.

### CROSS-REFERENCE TO RELATED APPLICATIONS

This application is based upon and claims the benefit of priority from prior Japanese Patent Application No. 2009-217745, filed on Sep. 18, 2009, the entire contents of which are incorporated herein by reference.

### BACKGROUND OF THE INVENTION

The present invention relates to a current sensor for detecting the magnitude of electric current flowing through a conductor.

A known current sensor uses a magnetic detection element such as a Hall element or a magnetoresistance effect element. The current detection performed by a current sensor that uses a Hall element will now be described.

When current flows through a current path such as a wire, the current forms a magnetic field near the current path. The strength of the magnetic field is proportional to the magnitude of the current. When a Hall element is arranged in the magnetic field formed near the current path, the Hall element generates a Hall voltage that is proportional to the current flowing through the current path. A current sensor that uses the Hall element detects the current flowing through the current path based on the Hall voltage.

However, when the strength of the magnetic field acting on the Hall element is low, the proportional relationship of the magnetic field strength and the Hall voltage becomes difficult to maintain. Further, the strength of the magnetic field generated by the current flowing through the current path is low in the first place. To increase the current detection sensitivity of the current sensor, Japanese Laid-Open Patent Publication No. 2002-303642 describes a magnetic core that concentrates the magnetic field generated by the current flowing through a current path and increases the strength of the magnetic field acting on the Hall element. A prior art current sensor including a magnetic core will now be described with reference to FIG. 8.

The current sensor of FIG. 8 is coupled to a bus bar 40. The bus bar 40 is used to supply power to, for example, a vehicle battery. The current sensor includes a magnetic core 31, a printed circuit board 33, and a case 34. The magnetic core 31 concentrates the magnetic field generated by the current flowing through the bus bar 40. Electronic components including a Hall element 32 are mounted on the printed circuit board 33. The case 34 accommodates the magnetic core 31 and the printed circuit board 33. The case 34 includes a sleeve 34a through which the bus bar 40 is inserted. The magnetic core 31 is C-shaped and includes a clearance CS (gap). The sleeve 34a is inserted into the middle of the space formed in the magnetic core 31 so that the magnetic core 31 surrounds the sleeve 34a and the bus bar 40. The clearance CS (gap) of the magnetic core 31 allows for insertion of the Hall element 32. The printed circuit board 33 is connected to a male terminal connector 35, which is arranged on an outer wall of the case 34. The magnetic core 31 concentrates and increases the magnetic field generated by the current flowing through the bus bar 40. Leakage flux generated in the clearance CS acts on the Hall element 32. The magnetic field acting on the Hall element 32 is amplified. This allows for the current sensor to detect the magnitude of a small current flowing through the bus bar 40. A detection signal corresponding to the Hall voltage of the Hall element 32 is provided to an in-vehicle device (not shown) via a conductor of the printed circuit board 33 and the male terminal connector 35.

### SUMMARY OF THE INVENTION

The bus bar 40 of the prior art sensor is just inserted into the sleeve 34a. Thus, the bus bar 40 may slightly move inside the sleeve 34a. Such displacement of the bus bar 40 changes the positional relationship between the magnetic core 31 and the bus bar 40. This changes the electric field that is concentrated and amplified by the magnetic core 31. As a result, the current sensor detection may become unstable, and the current detection accuracy may be lowered.

When the current sensor is provided with a structure for positioning the bus bar 40 so that the positional relationship between the magnetic core 31 and the bus bar 40 does not change, enlargement of the current sensor is unavoidable.

It is an object of the present invention to provide a compact current sensor that detects current with high accuracy.

One aspect of the present invention is a current sensor for outputting a detection signal corresponding to a current flowing through a bus bar. The current sensor includes a magnetic core that concentrates and amplifies a magnetic field generated by the current near a detection portion of the bus bar. A magnetic detection element detects the magnetic field concentrated by the magnetic core and outputs an electrical signal corresponding to the detected magnetic field. The detection portion of the bus bar and the magnetic core are molded integrally with each other.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a perspective view showing a current sensor according to one embodiment of the present invention;

FIG. 2 is a perspective exploded view showing the current sensor of FIG. 1;

FIG. 3 is a cross-sectional view showing the current sensor of FIG. 1;

FIG. 4 is a cross-sectional view taken along line 4-4 in FIG. 3;

FIG. 5 is a perspective view showing a first modification of the current sensor;

FIG. 6 is a perspective view showing a second modification of the current sensor;

FIG. 7 is a plan view showing a third modification of the current sensor; and

FIG. 8 is an exploded perspective view showing a current sensor of the prior art.

### DETAILED DESCRIPTION OF THE PREFERRED EMBODIMENTS

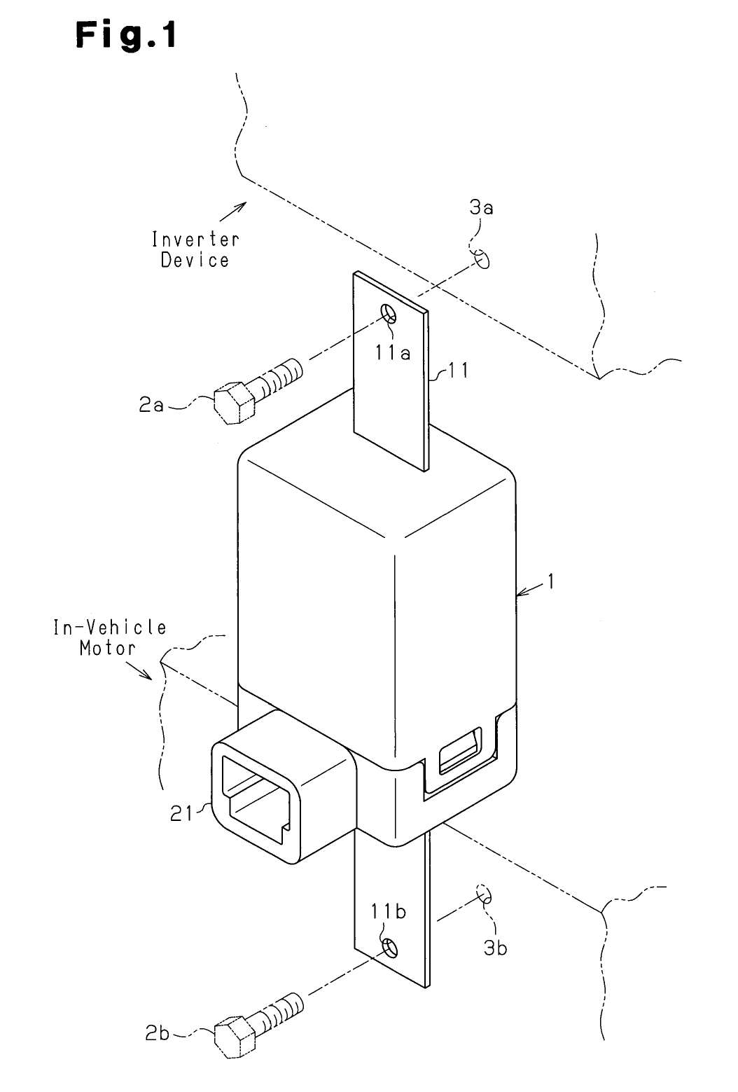

A current sensor according to one embodiment of the present invention will now be discussed with reference to FIGS. 1 to 4. First, the structure of the current sensor will be described with reference to FIG. 1.

As shown in FIG. 1, a case 1 covers electronic components of the current sensor. The case 1 protects the electronic components from the ambient environment. A connector 21 is arranged on the front of the case 1. The connector 21 is connected to a harness or the like (not shown) and may be used to supply the current sensor with power and to output a detection signal of the current sensor to an external device. A bus bar 11 having an elongated planar shape is attached to the case 1 in a state extending vertically through the case 1 as viewed in the drawing. The bus bar 11 is a power supply conductor and connects, for example, an in-vehicle inverter device and an in-vehicle motor. The bus bar 11 includes end portions that define coupling portions for coupling the current sensor to external devices. In the illustrated example, the two end portions of the bus bar 11 respectively have insertion holes 11a and 11b through which bolts 2a and 2b are inserted. The in-vehicle inverter device and the in-vehicle motor, which serve as the external devices, respectively include threaded holes 3a and 3b that correspond to the bolts 2a and 2b. The bolts 2a and 2b fasten the bus bar 11 to the in-vehicle inverter device and in-vehicle motor.

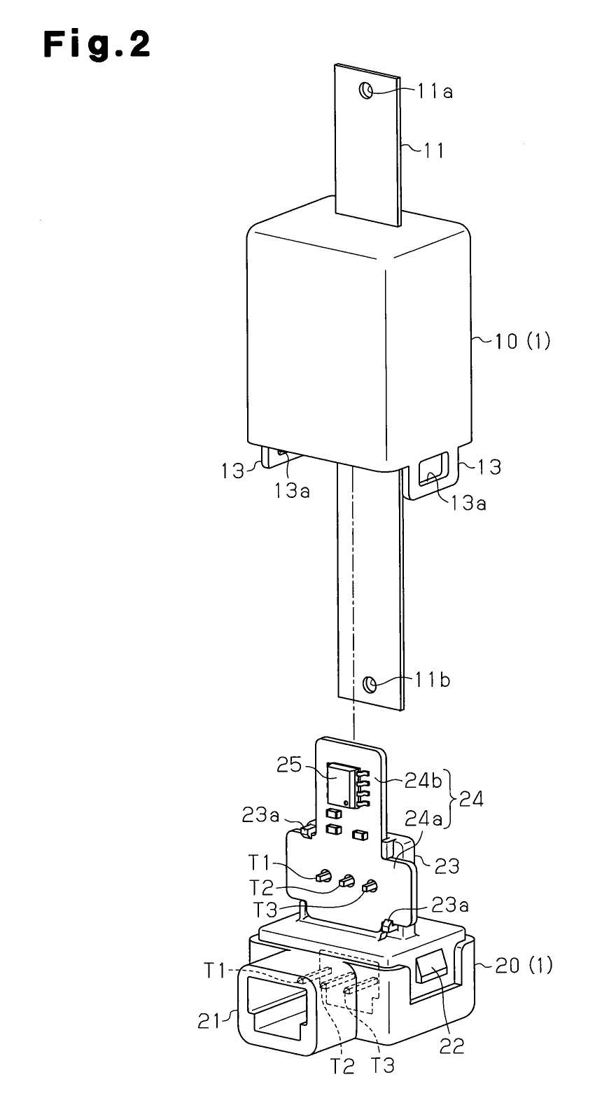

As shown in FIG. 2, the case 1 includes an upper case 10 and a lower case 20. The bus bar 11 is attached to the upper case 10. A tab 13 having a through hole 13a extends from the bottom of each of two opposing side walls of the upper case 10. The connector 21 is arranged on the lower case 20. A hook 22 is arranged on each of two opposing side walls of the lower case 20 to engage with the corresponding tab 13 of the upper case 10. The upper case 10 may be referred to as a first member, and the lower case 20 may be referred to as a second member. The case 1 is separable into the first and second members 10 and 20. This increases the design freedom for the case 1 and convenience for assembling the current sensor. In the illustrated example, the cases 10 and 20 are resin members formed from a resin material.

The engagement of the tabs 13 of the upper case 10 with the hooks 22 of the lower case 20 integrally couples the upper case 10 and the lower case 20 and forms the case 1. The tabs 13 and hooks 22 may be referred to as a fastening structure. The tabs 13 may be formed on the second member 20, and the hooks 22 may be formed on the first member 10.

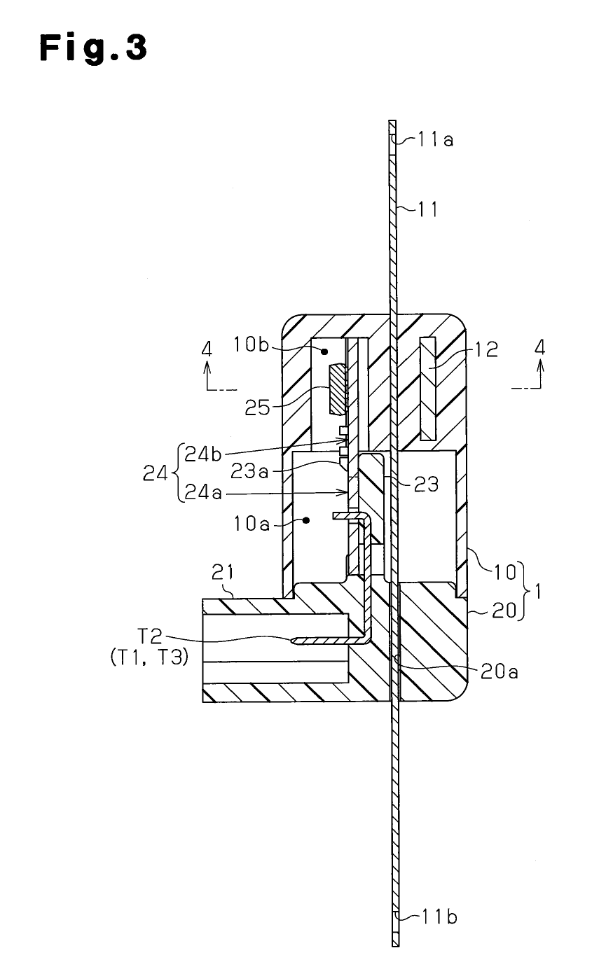

A planar substrate mount 23 projects from an upper surface of the lower case 20. The substrate mount 23 includes catches 23a. A printed circuit board 24 is fastened to the substrate mount 23 by the catches 23a. In the illustrated example, the printed circuit board 24 is T-shaped and includes a laterally extending plate 24a, which is held by the catches 23a, and a vertically extending plate 24b, which extends upward from the laterally extending plate 24a. A Hall IC 25 is mounted on the vertically extending plate 24b. A Hall element serving as a magnetic detection element (magnetoelectric conversion element) and its peripheral circuits are integrated in the Hall IC 25. Although not shown in the drawings, a processing circuit for processing output signals of the Hall IC 25 is also mounted on the printed circuit board 24. Basal portions of metal pins T1 to T3 are soldered to the laterally extending plate 24a of the printed circuit board 24. The metal pins T1 to T3 have distal portions extending into the connector 21 and functioning as a power supply terminal, an output terminal, and a ground (GND) terminal. Referring to FIG. 3, when molding the lower case 20 from resin, the metal pins T1 to T3 are integrally insert-molded, or embedded, in the lower case 20. An insertion hole 20a extends through the lower case 20 at the rear of the substrate mount 23. The bus bar 11 is inserted through the insertion hole 20a.

As shown in FIG. 3, the upper case 10 is capable of accommodating the substrate mount 23, the printed circuit board 24, and the Hall IC 25. The upper case 10 is divided into a large accommodation compartment 10a and a small accommodation compartment 10b respectively corresponding to the laterally extending plate 24a and vertically extending plate 24b of the printed circuit board 24. A detection portion of the bus bar 11 and the magnetic core 12 are integrally insert-molded, or embedded, in a wall of the small accommodation compartment 10b. The detection portion of the bus bar 11 and the magnetic core 12 are embedded integrally in the upper case 10, for example, when molding the upper case 10.

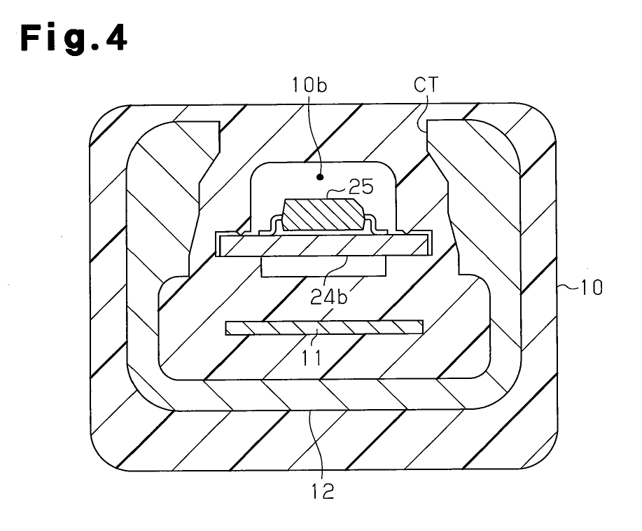

With reference to FIG. 4, the structure of the magnetic core 12 will now be described in detail.

The magnetic core 12 is a magnetic body. As shown in FIG. 4, the magnetic core 12 is a C-shaped member that surrounds the detection portion of the bus bar 11. The C-shaped member includes a clearance CT corresponding to the small accommodation compartment 10b. The magnetic core 12 has two opposing ends that define the clearance CT in between. The opposing ends of the magnetic core 12 are thicker than the other parts of the magnetic core 12. Each opposing end includes a stepped surface. The stepped surface is formed so that the clearance CT narrows from the inner side of the magnetic core 12 toward the outer side of the magnetic core 12. The Hall IC 25 accommodated in the small accommodation compartment 10b is located in the central part of the clearance CT.

Due to such a structure, the magnetic core 12 concentrates and amplifies the magnetic field generated by the current flowing through the bus bar 11 in the current sensor. The leakage flux in the clearance CT acts on the Hall IC 25 in the small accommodation compartment 10b. The Hall IC 25 outputs an electrical signal in correspondence with the current flowing through the bus bar 11.

In the magnetic core 31 of the prior art current sensor, the clearance CS has a constant width. The magnetic flux generated in the clearance CS of the constant width becomes smaller as the outer side of the magnetic core becomes closer. Further, the magnetic flux generated in the clearance CS becomes larger as the width of the clearance CS becomes smaller. In the present embodiment, the clearance CT narrows from the inner side of the magnetic core 12 toward the outer side of the magnetic core 12. Thus, magnetic flux is evenly generated in the clearance CT. This obtains the advantages described below.

In the prior art sensor, the magnetic field acting on the Hall element 32 slightly changes in accordance with the position of the Hall element 32 in the clearance CS of the magnetic core 31. Thus, when the Hall element 32 is displaced in the clearance CS, the current sensor may not be able to detect current with high accuracy. To detect current with high accuracy, the Hall element 32 and the magnetic core 31 must be accurately positioned. However, accurate positioning of the Hall element 32 and the magnetic core 31 would increase manufacturing processes for the current sensor. This would raise the manufacturing cost for the current sensor. In this respect, the magnetic core 12 of the present embodiment evenly generates magnetic flux in the clearance CT. Thus, the magnetic field acting on the Hall IC 25 subtly changes even when, for example, assembling tolerances of the cases 10 and 20 displace the Hall IC 25 in the clearance CT. Consequently, the current sensor of the present embodiment detects current with high accuracy and reduces manufacturing costs without requiring the Hall IC 25 to be positioned with high accuracy.

In the present embodiment, the detection portion of the bus bar 11 and the magnetic core 12 are molded integrally with each other. This prevents relative displacement of the detection portion of the bus bar 11 and the magnetic core 12. Thus, the current sensor stably detects current with high accuracy. Further, since the detection portion of the bus bar 11 and the magnetic core 12 are molded integrally with each other, there is no need for a structure that positions the bus bar 11. This allows for the current sensor to be compact and detect current with high accuracy.

The current sensor of the present embodiment has the advantages described below.

(1) The detection portion of the bus bar 11 and the magnetic core 12 are molded integrally with each other. This prevents relative displacement of the detection portion of the bus bar 11 and the magnetic core 12 without a structure for positioning the bus bar 11, and allows for the current sensor to be compact and detect current with high accuracy.

(2) The case 1 includes the upper case 10, which accommodates the detection portion of the bus bar 11 and the magnetic core 12, and the lower case 20, which accommodates the printed circuit board 24 on which the Hall IC 25 is mounted. The current sensor is assembled just by coupling the case 10 and 20 to each other. In other words, the current sensor is formed by the separable cases 10 and 20. This facilitates the assembling of the current sensor.

(3) The opposing ends of the magnetic core 12 defining the clearance CT each includes a stepped surface that is formed so that leakage flux is evenly generated in the clearance CT. Thus, displacement of the Hall IC in the clearance CT would only subtly change the magnetic field acting on the Hall IC 25. This eliminates the need for positioning the Hall IC 25 with high accuracy and thereby reduces manufacturing cost for the current sensor.

It should be apparent to those skilled in the art that the present invention may be embodied in many other specific forms without departing from the scope of the invention. Particularly, it should be understood that the present invention may be embodied in the following forms.

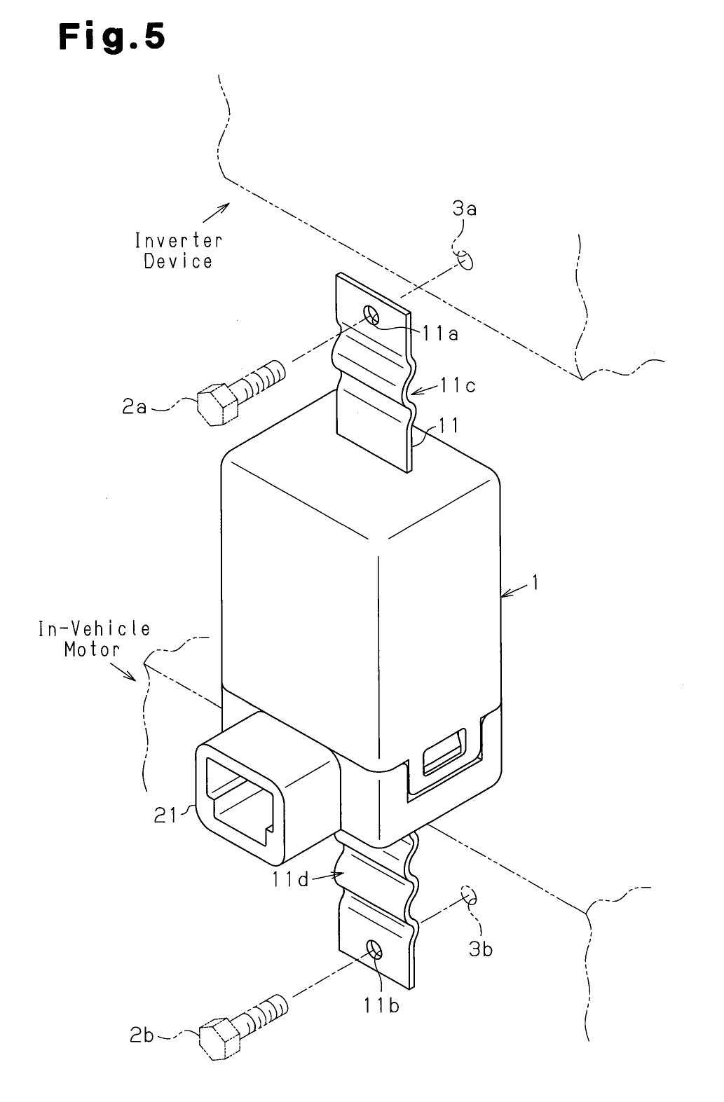

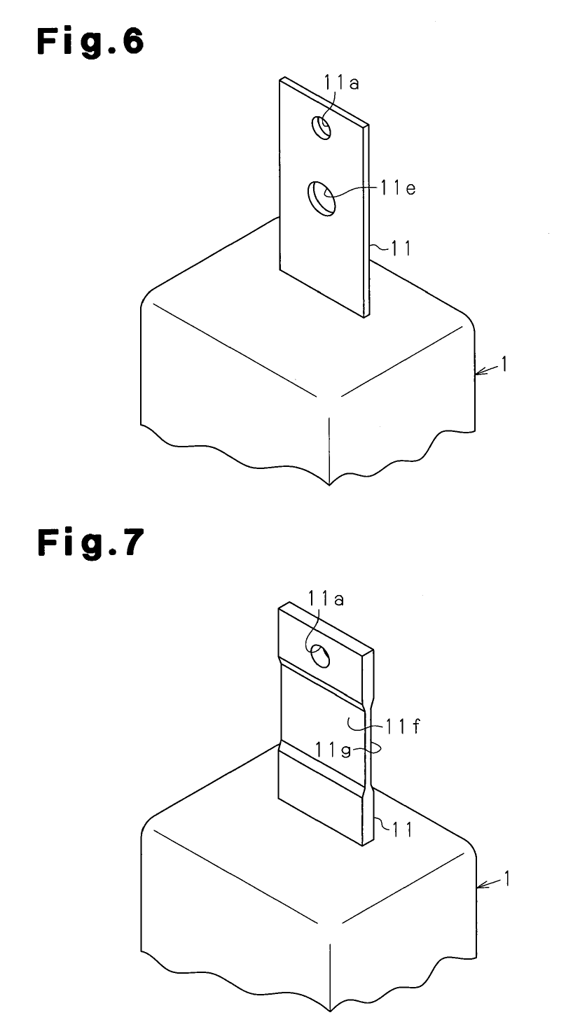

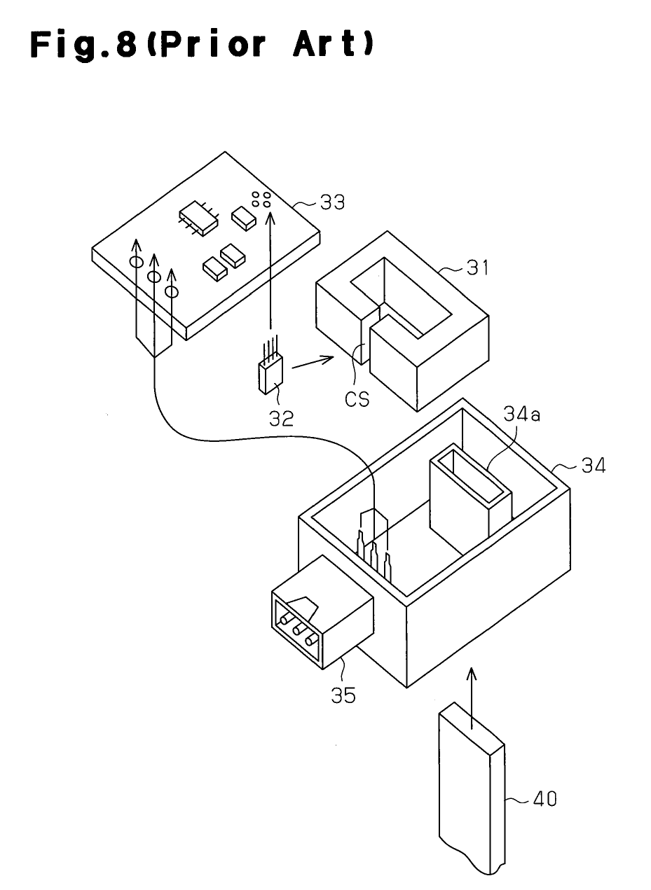

As shown in FIG. 5, the bus bar 11 may include undulated portions 11c and 11d between the case 1 and the insertion holes 11a and 11b. The undulated portions 11c and 11d absorb the stress applied to the bus bar 11 when fastening the bolts 2a and 2b and decrease or eliminate the stress applied to the electronic components of the current sensor. This prevents the electronic components of the current sensor from being damaged. Instead of the undulated portions 11c and 11d, the bus bar 11 may include through holes 11e (refer to FIG. 6) or recesses 11f and 11g (refer to FIG. 7). The recesses 11f and 11g of FIG. 7 are formed in the front and rear surfaces of the bus bar 11 and provide the bus bar 11 with partially thin portions. These structures also absorb the stress applied to the bus bar 11 and thereby have the advantages described above.

In the above-discussed embodiment, to form the clearance CT in the magnetic core 12 that narrows from the inner side toward the outer side of the magnetic core 12, stepped surfaces are formed in the opposing ends defining the clearance CT. The stepped surfaces may each be a smooth sloped surface. Depending on the shape of the magnetic core 12 and the shape of the detection portion of the bus bar 11, the clearance CT may be formed so that it widens from the inner side toward the outer side of the magnetic core 12. It is only required that the clearance CT be adjusted so that leakage flux is evenly generated in the clearance CT when concentrating and amplifying the magnetic field generated near the detection portion of the bus bar 11. Adjustment of the clearance CT includes, for example, widening or narrowing the clearance CT continuously or in a stepped manner.

In the above-discussed embodiment, the clearance CT of the magnetic core 12 is formed so as to narrow from the inner side toward the outer side of the magnetic core 12. Instead, the clearance CT of the magnetic core 12 may have a constant width when relative displacement of the Hall IC 25 relative to the magnetic core 12 is ignorable such as when the magnetic core 12 is sufficiently larger than the Hall IC 25. Such a structure would also have advantages that are the same or similar to advantages (1) and (2), which are described above.

In the above-discussed embodiment, the Hall IC 25 is used to detect leakage flux generated in the clearance CT. A magnetoresistance effect element may be used in lieu of the Hall IC 25. The magnetoresistance effect element has a resistance that is changed by a magnetoresistance effect in accordance with the magnetic field.

In the above-discussed embodiment, the bus bar 11 is a conductor that connects the in-vehicle inverter device and in-vehicle motor. The bus bar 11 may also be a power supply conductor connected to a vehicle battery.

The in-vehicle inverter device and in-vehicle motor may be arranged in a so-called hybrid vehicle.

The present examples and embodiments are to be considered as illustrative and not restrictive, and the invention is not to be limited to the details given herein, but may be modified within the scope and equivalence of the appended claims.

What is claimed is:

1. A current sensor for outputting a detection signal corresponding to a current flowing through a bus bar, the current sensor comprising:
a magnetic core that concentrates and amplifies a magnetic field generated by the current near a detection portion of the bus bar; and
a magnetic detection element that detects the magnetic field concentrated by the magnetic core and outputs an electrical signal corresponding to the detected magnetic field;
wherein the detection portion of the bus bar and the magnetic core are molded integrally with each other.

2. The current sensor according to claim 1, further comprising:
a first member integrally including the detection portion of the bus bar and the magnetic core; and
a second member including a substrate on which the magnetic detection element is mounted;
wherein the current sensor is formed by coupling the first member and the second member each other.

3. The current sensor according to claim 1, wherein the magnetic core includes two opposing ends that define a clearance in between, the magnetic core includes the detection portion of the bus bar, the magnetic detection element is arranged in the clearance of the magnetic core, and the clearance is adjusted so that leakage flux is evenly generated in the clearance when the magnetic core concentrates and amplifies a magnetic field.

4. The current sensor according to claim 1, wherein the bus bar is planar and includes an end portion defining a coupling portion that couples the current sensor to an external device, and the bus bar further includes a stress absorption structure between the detection portion and the coupling portion.

5. The current sensor according to claim 3, wherein the clearance narrows from an inner side to an outer side of the magnetic core.

6. The current sensor according to claim 1, wherein the detection portion of the bus bar and the magnetic core are embedded integrally with each other in a resin member.
